(19) United States
(12) Patent Application Publication
(10) Pub. No.: US 2008/0151499 A1
(43) Pub. Date: Jun. 26, 2008

(54) Electronic device and heat dissipation module thereof

(75) Inventor: Tui-Yang Tsai, Tao Yuan Shien (TW)

Correspondence Address: RABIN & Berdo, PC, 1101 14TH STREET, NW, SUITE 500, WASHINGTON, DC, 20005, US

(73) Assignee: Quanta Computer Inc., Tao Yuan Shien (TW)

(21) Appl. No.: 11/723,495

(22) Filed: Mar. 20, 2007

(30) Foreign Application Priority Data
Dec. 26, 2006 (TW) 95149054

(51) Int. Cl. H05K 7/20

(52) U.S. Cl. 361/697

(57) ABSTRACT

An electronic device and a heat dissipation module thereof are provided. The heat dissipation module includes a base, a plurality of fins, a fan and a Stirling engine. The base is disposed on a heat source. The fins are connected with the base. The fan blows towards the fins. The Stirling engine has a power inlet disposed on the base and a power outlet connected with the fan. The Stirling engine is utilized to cool the heat source using the heat generated thereby.

### RELATED APPLICATIONS

The present application claims priority to Taiwan Application Serial Number 95149054, filed Dec. 26, 2006, which is herein incorporated by reference.

### BACKGROUND OF THE INVENTION

1. Field of Invention

The invention relates to an electronic device and the heat dissipation module thereof. In particular, the invention relates to an electronic device and its heat dissipation module that has a Stirling engine.

2. Related Art

Electronic devices such as computers, audio/video (AV) players, and projectors have been welcomed and widely used by the public. To provide more and better functions, the chips with faster operating speeds of the electronic devices are necessary. However, there is also the problem with heat dissipation at the same time. In particular, a lot of heat is produced when the chip is operating at a high speed. If the heat accumulates on the chip and cannot be immediately removed, the chip may not be able to function well or even shut down the entire electronic device. Therefore, fast heat dissipation is a very important issue for the electronic device to function in an optimal way.

Most electronic devices only use a heat dissipation module, in which the electronic element that needs heat dissipation is disposed with fins. A fan is used to blow cool air to the heat dissipation module, bringing away the heat produced by the electronic element. Generally speaking, additional electrical power is required to drive the fan in such heat dissipation modules. However, it is also a crucial issue to save energy consumed by the electronic devices. Therefore, it is more desirable to provide a heat dissipation module that can generate cool airflow without using additional electrical power.

### SUMMARY OF THE INVENTION

An objective of the invention is to provide a heat dissipation module that has a Stirling engine for using the heat produced by the heat source to blow cool air to the heat source.

It is also an objective of the invention to provide an electronic device whose heat dissipation module has a Stirling engine. The Stirling engine is utilized to cool the heat source using the heat generated thereby.

In accordance with the above-mentioned objectives, the disclosed heat dissipation module includes a base, several fins, a fan, and a Stirling engine. The base is disposed on a heat source. The fins are connected with the base. The fan blows towards the fins. The Stirling engine has a power inlet disposed on the base and a power outlet connected with the fan. The Stirling engine is utilized to remove the heat from the heat source using the heat generated thereby.

In accordance with the above-mentioned objectives, the disclosed electronic device has a case, a circuit board, a base, several fins, a fan, and a Stirling engine. The circuit board is disposed inside the case and has an electronic element thereon. The base is disposed on the electronic element. The fins are connected with the base. The fan blows to the fins. The Stirling engine has a power inlet disposed on the base and a power outlet connected with the fan. The Stirling engine is utilized to cool the electronic element using the heat generated thereby.

According to a preferred embodiment of the invention, the heat dissipation module further includes a heat insulating board disposed between the Stirling engine and the fins. The heat insulating board can effectively prevent the heat dissipated from the fins from being transferred to the Stirling engine and reducing its efficiency.

According to another embodiment of the invention, the heat dissipation module further includes a heat mediator disposed between the base and the heat source so that the heat source and the base have a closer contact, enhancing the heat transfer efficiency between them.

According to a preferred embodiment of the invention, the heat dissipation module of the electronic device has a Stirling engine for removing the heat from the heat source using the heat generated thereby.

The electronic device and the heat dissipation module in yet another embodiment of the invention can adjust its heat-dissipating efficiency according to the temperature of the heat source.

### BRIEF DESCRIPTION OF THE DRAWINGS

These and other features, aspects and advantages of the invention will become apparent by reference to the following description and accompanying drawings which are given by way of illustration only, and thus are not limitative of the invention, and wherein:

FIG. 1 schematically shows the structure of the heat dissipation module according to the preferred embodiment; and

FIG. 2 schematically shows the structure of the electronic device according to the preferred embodiment.

### DETAILED DESCRIPTION OF THE INVENTION

The present invention will be apparent from the following detailed description, which proceeds with reference to the accompanying drawings, wherein the same references relate to the same elements.

The heat dissipation module for electronic devices in the prior art is usually driven by electrical power. The invention discloses an electronic device and the heat dissipation module thereof that utilize a Stirling engine to generate airflow to cool a heat source using the heat generated thereby.

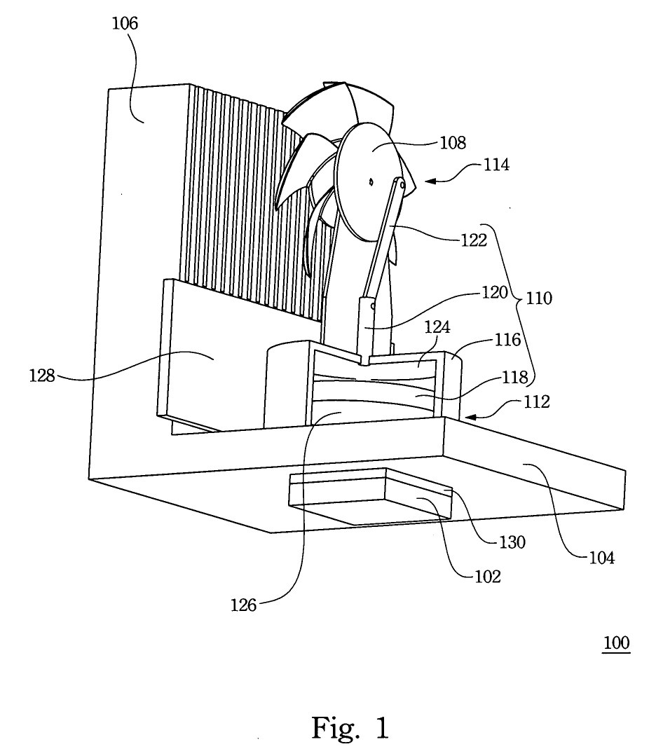

With reference to FIG. 1, a heat dissipation module 100 is used to dissipate heat generated by a heat source 102. The heat dissipation module 100 includes a base 104, several fins 106, a fan 108, and a Stirling engine 110. The heat source 102 may be a chip or a light-emitting diode (LED), for example. The base 104 and the fins 106 are made of materials with large coefficients of thermal conductivity, such as aluminum and copper. Moreover, the base 104 and the fins 106 can be integrally formed. The base 104 is disposed on the heat source 102. The fins 106 are connected with the base 104. The base 104 absorbs heat generated by the heat source 102 and transfers the heat to the fins 106. Consequently, the heat generated by the heat source 102 is dissipated to the environment via the base 104 and the fins 106.

With further reference to FIG. 1, the Stirling engine 110 has a power inlet 112 disposed on the base 104 and a power outlet 114 connected with the fan 108. The Stirling engine 110 uses the heat generated by the heat source 102 to drive the fan 108 to rotate and thus producing cooling airflow blown to the fins 106. The cooling airflow would passes the fins 106 when the fan 108 operates and that increases the heat-dissipating efficiency of the fins 106, therefore the heat produced by the heat source 102 can be more quickly removed from the fins 106.

More explicitly, the Stirling engine 110 includes a cylinder 116, a piston 118, a piston shaft 120, and a transmission shaft 122. The piston 118 is disposed inside the cylinder 116, separating the cylinder 116 into a first chamber 124 and a second chamber 126. One end of the cylinder 116 that encloses the second chamber 126 is in contact with the base 104 which result in temperature difference between the first chamber 124 and the second chamber 126 and the air inside the first chamber 124 and the second chamber 126 expands at different rates, and therefore the piston 118 performs a reciprocal motion inside the cylinder 116. The piston shaft 120 is connected to the piston 118. One end of the transmission shaft 122 is connected with the piston shaft 120, and the other end is connected with the fan 108. The transmission shaft 122 converts the reciprocal horizontal motion of the piston 118 and the piston shaft 120 into a rotational motion of the fan 108, generating cooling airflow. Therefore, the Stirling engine 110 can use the heat generated by the heat source 102 to drive the fan 108 and produce cooling airflow to dissipate heat from the heat source 102. It should be mentioned that the more heat the heat source 102 generates, the larger the temperature difference between the heat source 102 and the environment is, and thus the rotational speed of the fan 108 driven by the Stirling engine becomes larger which producing larger cooling airflow and heat-dissipation effects. In other words, the heat dissipation module 100 can automatically adjust the rotational speed of the fan 108 according to the temperature of the heat source 102. Therefore, the invention can effectively prevent the heat source 102 from overheating.

Please continue to refer to FIG. 1. The rotational speed of the fan 108 driven by the Stirling engine 110 depends on the temperature difference between the first chamber 124 and the second chamber 126. To prevent the heat dissipated by the fins 106 from being transferred to the cylinder 116, reducing the temperature difference between the first chamber 124 and the second chamber 126 and the efficiency of the Stirling engine 110, a heat insulating board 128 is disposed on the base 104, between the cylinder 116 and the fins 106. The material of the heat insulating board 128 can be ceramic or other heat insulating material. Its height is higher than the height of the cylinder 116, and its width is greater than the diameter of the cylinder 116. This can effectively prevent the heat dissipated by the fins 106 from being transferred to the sidewall of the cylinder 116. Otherwise, the heat will result in a reduced temperature difference between the first chamber 124 and the second chamber 126 which reducing efficiency for the Stirling engine 110.

It should be noted that a heat mediator, such as a heat conductive tape or ointment, can be disposed between the base 104 and the heat source 102, so that the heat source 102 and the base 104 have a closer contact which enhance the heat transfer efficiency between them.

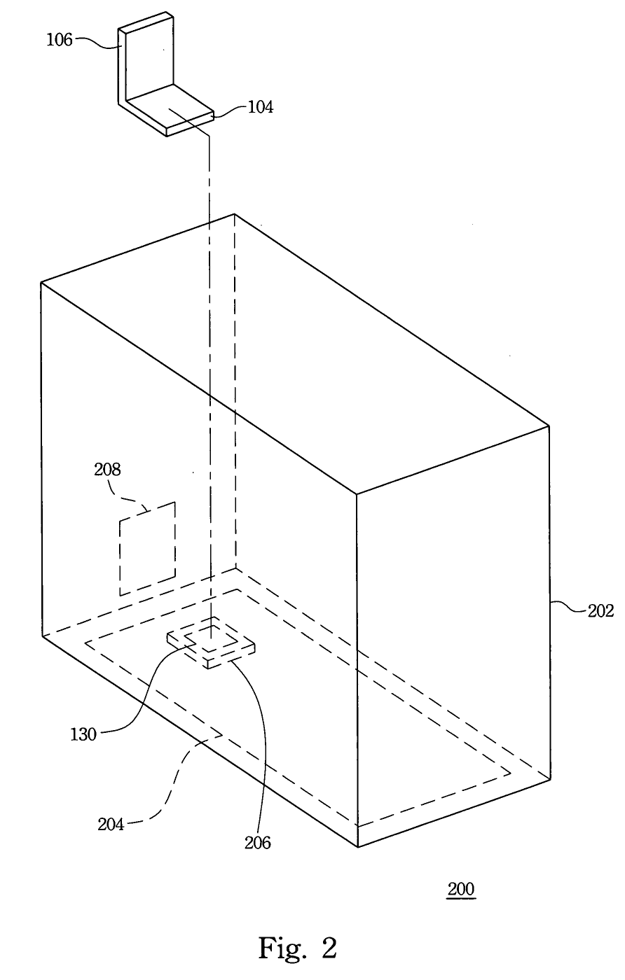

Please refer to FIGS. 1 and 2. An electronic device 200 such as a computer, AV player, or projector according to the invention has a structure shown in FIG. 2. Its circuit board 204 is disposed in a case 202. The circuit board 204 has an electronic element 206, such as a chip or LED that generates heat. The base 104 is disposed on the electronic element 206. The fins 106 are connected with the base 104. The Stirling engine 110 (FIG. 1) can be disposed on the base 104 for cooling the electronic element 206 or other element inside the case 202 by utilizing the heat from electronic element 206.

It should be noted that a heat mediator 130, such as a heat conductive tape or ointment, can be disposed between the base 104 and the electronic element 206. Besides, the case 202 has an opening 208. The fan 108 (shown in FIG. 1) flows towards the opening 208, so that the heat dissipated from the fins 106 would be brought out of the case 202 via the opening 208.

In accord with the above-mentioned embodiments, the invention has the following advantages:

1. The electronic device and its heat dissipation module according to the preferred embodiment do not require additional electrical power. It cools the heat source using the heat generated thereby.

2. The electronic device and its heat dissipation module according to the preferred embodiment can automatically adjust the heat dissipation efficiency according to the temperature of the heat source.

While the invention has been described by way of example and in terms of the preferred embodiment, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A heat dissipation module for cooling a heat source, which comprises:
a base disposed on the heat source;
a plurality of fins connected with the base;
a fan blowing towards the fins; and
a Stirling engine having a power inlet disposed on the base and a power outlet connected with the fan for cooling the heat source using the heat generated thereby.

2. The heat dissipation module of claim 1, wherein the Stirling engine includes:
a cylinder;
a piston disposed inside the cylinder;
a piston shaft connected with the piston; and
a transmission shaft with one end connected with the piston shaft and the other end connected with the fan.

3. The heat dissipation module of claim 2, wherein the piston separates the cylinder into a first chamber and a second chamber in contact with the base so that a temperature difference establishes between them.

4. The heat dissipation module of claim 1 further comprising a heat insulating board disposed between the cylinder and the fins.

5. The heat dissipation module of claim 1, wherein the heat source is an electronic element.

6. The heat dissipation module of claim 1 further comprising a heat mediator disposed between and in contact with the base and the heat source.

7. An electronic device, which comprises:
a case;
a circuit board disposed inside the case with an electronic element thereon;
a base disposed on the electronic element;
a plurality of fins connected with the base;
a fan blowing towards the fins; and
a Stirling engine having a power inlet disposed on the base and a power outlet connected with the fan for cooling the heat source using the heat generated thereby.

8. The electronic device of claim 7, wherein the Stirling engine includes:
a cylinder;
a piston disposed inside the cylinder;
a piston shaft connected with the piston; and
a transmission shaft with one end connected with the piston shaft and the other end connected with the fan.

9. The electronic device of claim 8, wherein the piston separates the cylinder into a first chamber and a second chamber in contact with the base so that a temperature difference establishes between them.

10. The electronic device of claim 7 further comprising a heat insulating board disposed between the cylinder and the fins.

11. The electronic device of claim 7, wherein the electronic element is an electronic element.

12. The electronic device of claim 7 further comprising a heat mediator disposed between and in contact with the base and the electronic element.
